(19) United States
(12) Patent Application Publication
(10) Pub. No.: US 2025/0160042 A1
(43) Pub. Date: May 15, 2025

(54) HIGH PERFORMANCE LONG-LIFETIME CHARGE-SEPARATION PHOTODETECTORS

(71) Applicants: Arizona Board of Regents on behalf of Arizona State University, Scottsdale, AZ (US); The Board of Trustees of the University of Arkansas, Little Rock, AR (US)

(72) Inventors: Yong-Hang Zhang, Scottsdale, AZ (US); Shui-Qing Yu, Fayetteville, AR (US)

(21) Appl. No.: 19/021,703

(22) Filed: Jan. 15, 2025

Related U.S. Application Data
(62) Division of application No. 17/356,185, filed on Jun. 23, 2021, now abandoned.
(60) Provisional application No. 63/042,814, filed on Jun. 23, 2020.

(51) Int. Cl. H10F 77/122; H10F 30/223; H10F 71/00

(52) U.S. Cl. CPC H10F 77/122; H10F 30/223; H10F 71/1215

(57) ABSTRACT

High-performance long-lifetime charge-separation photodetectors are provided. A new device design is described based on novel band structure engineering of semiconductor materials for photodetectors, such as photosensors, solar cells, and thermophotovoltaic devices. In an exemplary aspect, photodetectors described herein include a charge-separated photo-absorber region. This comprises a semiconductor with a band structure that has an indirect fundamental bandgap, with a direct bandgap (Γ-Γ transition) only slightly above the indirect fundamental bandgap (L- or X-Γ transitions) (e.g., approximately equal to or larger than an energy of a product of the Boltzmann constant (k_{B}), and temperature (T), with k_{B}T=26 millielectron-volts (meV) at room temperature). This design not only improves photogenerated-carrier lifetime (similar to indirect bandgap semiconductors), but also maintains a strong absorption coefficient (similar to direct bandgap semiconductors).

### RELATED APPLICATIONS

This application is a divisional of U.S. patent application Ser. No. 17/356,185, filed Jun. 23, 2021, which claims the benefit of provisional patent application Ser. No. 63/042,814, filed Jun. 23, 2020, the disclosures of which are hereby incorporated herein by reference in their entireties.

### GOVERNMENT SUPPORT

This invention was made with government support under FA9550-19-1-0341 awarded by the Air Force Office of Scientific Research and under W911NF-19-1-0227 awarded by the Army Research Office. The government has certain rights in the invention.

### FIELD OF THE DISCLOSURE

The present disclosure relates to high-performance photodetectors, including photosensors, solar cells, and thermophotovoltaic devices.

### BACKGROUND

The materials and device structures of photodetectors (e.g., photosensors, solar cells, and thermophotovoltaic devices) have been studied for over half a century. However, the performance of state-of-the-art photodetectors is quite far from theoretical limits. In addition, manufacturing costs of photodetectors are high due to the expensive materials used and complicated structure designs and processes, which prevent them from being used in many high-volume applications.

Traditionally, infrared (IR) and other wavelength photodetectors are designed based on available materials (e.g., mercury cadmium telluride (HgCdTe), silicon (Si), indium gallium arsenide (InGaAs), lead selenide (PbSe), and gallium nitride (GaN)) with limited flexibility of band structures and other material properties. For instance, Si has an indirect bandgap, which gives a very long carrier lifetime but a very small absorption coefficient. Therefore, Si photodetectors require a very thick layer to have enough absorption, which, in return, contains a larger total number of Shockley-Read-Hall (SRH) recombination centers that are volume dependent.

On the other hand, direct bandgap semiconductors, such as InGaAs and HgCdTe, have a much larger absorption coefficient (i.e., thinner necessary absorber thickness), which leads to fewer SRH recombination centers. However, the carrier lifetime in direct bandgap semiconductors is much shorter than that in indirect bandgap semiconductors and is very sensitive to SRH and Auger recombinations. Therefore, the requirements of the material quality for this kind of photodetector are very high so that the manufacturing processes are very sophisticated with high costs. It is, therefore, important to find materials that can combine the advantages of both direct and indirect bandgaps for light detection/conversion (e.g., photosensors, solar cells, and thermophotovoltaic) devices.

### SUMMARY

High-performance long-lifetime charge-separation photodetectors are provided. A new device design is described based on novel band structure engineering of semiconductor materials for photodetectors, such as photosensors, solar cells, and thermophotovoltaic devices. In an exemplary aspect, photodetectors described herein include a charge-separated photo absorber region. This comprises a semiconductor with a band structure that has an indirect fundamental bandgap, with a direct bandgap (Γ-Γ transition) only slightly above the indirect fundamental bandgap (L- or X-Γ transitions) (e.g., approximately equal to or larger than an energy of a product of the Boltzmann constant (k_{B}), and temperature (T), with k_{B}T=26 millielectron-volts (meV) at room temperature). This design not only improves photogenerated-carrier lifetime (similar to indirect bandgap semiconductors), but also maintains a strong absorption coefficient (similar to direct bandgap semiconductors).

Embodiments of this type of design can use a material system with one or more of silicon germanium tin lead (SiGeSnPb), gallium arsenic phosphide (GaAsP), aluminum gallium arsenide (AlGaAs), or gallium indium aluminum arsenic antimonide (GaInAlAsSb). This photodetector design has very broad applications that include night-vision for autonomous automobiles and defense applications, silicon photonics for communication and sensing, chemical sensing for environmental monitoring, biomedical applications, and energy conversion such as solar cells and thermophotovoltaic devices.

An exemplary embodiment provides a photo-absorbing semiconductor. The photo-absorbing semiconductor includes a substrate; and an absorber region on the substrate having a band structure with a direct bandgap having an energy between 0.5 k_{B}T and 10 k_{B}T greater than an energy of an indirect fundamental bandgap, wherein k_{B} represents a Boltzmann constant and T represents a device operation temperature.

Another exemplary embodiment provides a charge-separation photodetector. The charge-separation photodetector includes a first contact; a second contact; and a photo-absorbing semiconductor coupled to the first contact and the second contact, wherein the photo-absorbing semiconductor has a band structure with a direct bandgap having an energy above an energy of an indirect fundamental bandgap such that incoming photons are absorbed by direct transitions with high absorption coefficients inside the photo-absorbing semiconductor to induce a photo-generated change in an electrical property across the first contact and the second contact.

Another exemplary embodiment provides a method for producing a photodetector. The method includes providing a substrate; and forming an absorber region on the substrate with a photo-absorbing semiconductor having a band structure with a direct bandgap having an energy between 0.5 k_{B}T and 10k_{B}T greater than an energy of an indirect fundamental bandgap, wherein k_{B} represents a Boltzmann constant and T represents a device operation temperature.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A illustrates a cross-sectional block diagram of a charge-separation photodetector incorporating a photo-absorbing semiconductor, according to embodiments described herein;

FIG. 1B illustrates a cross-sectional block diagram of an alternate embodiment of the charge-separation photodetector of FIG. 1A;

FIG. 2 illustrates a schematic diagram of a photodetector device modeled as a p-n junction or p-i-n diode;

FIG. 3 illustrates a graphical representation of published lowest dark current density data in type-II superlattice photodetectors compared with that of mercury cadmium telluride (HgCdTe, also referred to as MCT) devices (the Rule 07 curve);

FIG. 4A illustrates a basic working principle of momentum (k)-space charge-separation (k-SCS);

FIG. 4B illustrates a schematic diagram of an absorption spectrum of an exemplary charge-separation photodetector;

FIG. 5 illustrates a graphical representation of bandgap energy between a direct bandgap and an indirect fundamental bandgap as a function of tin (Sn) composition in germanium-tin (GeSn) alloy photodetectors;

FIG. 6A is a graphical representation of an energy-momentum (E-k) diagram illustrating characteristics of a traditional photodetector;

FIG. 6B is a graphical representation of an E-k diagram illustrating characteristics of an embodiment of the charge-separation photodetector;

FIG. 6C is a graphical representation of an E-k diagram illustrating characteristics of a photodetector with a direct fundamental bandgap;

FIG. 7A is a graphical representation of an E-k diagram illustrating characteristics of a germanium- (Ge-)only photodetector;

FIG. 7B is a graphical representation of an E-k diagram illustrating characteristics of a SiₓGe_{1-x-y}Sn_{y} embodiment of the charge-separation photodetector;

FIG. 7C is a graphical representation of an E-k diagram illustrating characteristics of a longer wavelength, higher Sn/Silicon (Si) composition SiₚGe_{1-p-q}Sn_{q} embodiment of the charge-separation photodetector;

FIG. 8 illustrates a graphical representation of bandgap energy vs. lattice constant modeled for several transitions;

FIG. 9 illustrates a graphical representation of band structure modeling of SiₓGe_{1-x-y}Sn_{y}; and

FIGS. 10A-10D illustrate graphical representations of band structure modeling of SiₓGe_{1-x-y}Sn_{y} with different substrates.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It should be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It should also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It should be understood that, although the terms “upper,” “lower,” “bottom,” “intermediate,” “middle,” “top,” and the like may be used herein to describe various elements, these elements should not be limited by these terms. These terms are only used to distinguish one element from another. For example, a first element could be termed an “upper” element and, similarly, a second element could be termed an “upper” element depending on the relative orientations of these elements, without departing from the scope of the present disclosure.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having meanings that are consistent with their meanings in the context of this specification and the relevant art and will not be interpreted in an idealized or overly formal sense unless expressly so defined herein.

Fundamental bandgap: As used herein, a “fundamental bandgap” is the smallest bandgap of a semiconductor. A fundamental bandgap can be direct or indirect.

Direct bandgap: As used herein, a “direct bandgap” is a Γ-Γ energy transition, where the valence band maximum of a semiconductor is Γ. A direct bandgap can be the fundamental bandgap, in which case the semiconductor can be referred to as a “direct bandgap semiconductor.”

Indirect bandgap: As used herein, an “indirect bandgap” is the energy gap of a semiconductor for L-Γ or X-Γ transitions. An indirect bandgap can be the fundamental bandgap, in which case the semiconductor can be referred to as an “indirect bandgap semiconductor.”

L valley, X valley, Γ valley: As used herein, an “L valley,” an “X valley,” and a “Γ valley” are energy minima points in the conduction band of a semiconductor.

High-performance long-lifetime charge-separation photodetectors are provided. A new device design is described based on novel band structure engineering of semiconductor materials for photodetectors, such as photosensors, solar cells, and thermophotovoltaic devices. In an exemplary aspect, photodetectors described herein include a charge-separated photo absorber region. This comprises a semiconductor with a band structure that has an indirect fundamental bandgap, with a direct bandgap (Γ-Γ transition) only slightly above the indirect fundamental bandgap (L- or X-Γ transitions) (e.g., approximately equal to or larger than an energy of a product of the Boltzmann constant (k_{B}), and temperature (T), with k_{B}T=26 millielectron-volts (meV) at room temperature). This design not only improves photogenerated-carrier lifetime (similar to indirect bandgap semiconductors), but also maintains a strong absorption coefficient (similar to direct bandgap semiconductors).

Embodiments of this type of design can use a material system with one or more of silicon germanium tin lead (SiGeSnPb), gallium arsenic phosphide (GaAsP), aluminum gallium arsenide (AlGaAs), or gallium indium aluminum arsenic antimonide (GaInAlAsSb). This photodetector design has very broad applications that include night-vision for autonomous automobiles and defense applications, silicon photonics for communication and sensing, chemical sensing for environmental monitoring, biomedical applications, and energy conversion such as solar cells and thermophotovoltaic devices.

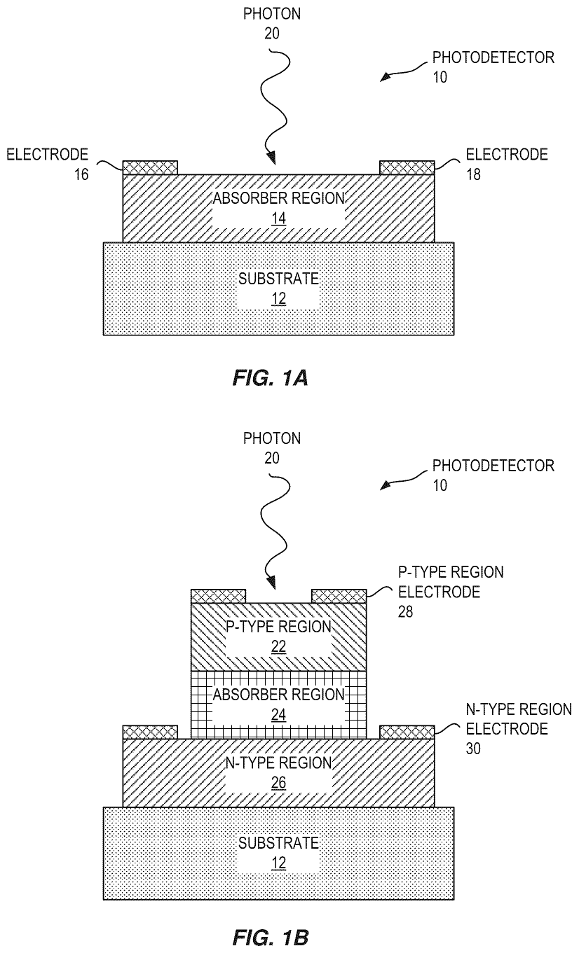

FIG. 1A illustrates a cross-sectional block diagram of a charge-separation photodetector 10 incorporating a photo-absorbing semiconductor, according to embodiments described herein. In this regard, the charge-separation photodetector 10 includes a substrate 12 and an absorber region 14 on the substrate 12. An electrical connection can be provided through a first electrode 16 (e.g., an anode) and a second electrode 18 (e.g., a cathode) connected to the absorber region 14. It should be understood that the depicted positions of the first electrode 16 and the second electrode 18 are illustrative in nature and, in other embodiments, they may be positioned differently (e.g., switched with each other, positioned vertically as in FIG. 1B, or positioned over different portions of the absorber region 14).

The absorber region 14 comprises a photo-absorbing semiconductor, which absorbs light energy from photons 20 incident on a surface of the charge-separation photodetector 10. As the photons 20 are absorbed, a change in the resistance between the first electrode 16 and the second electrode 18 is produced. As described further below, the photo-absorbing semiconductor of the absorber region 14 comprises a semiconductor with a band structure that has an indirect fundamental bandgap, with a direct bandgap only slightly above (e.g., above and near or adjacent) the indirect fundamental bandgap. The charge-separation photodetector 10 of FIG. 1A is illustrated as a photoconductor, but it should be understood that other types of photodetectors (including photosensors, solar cells, and thermophotovoltaic devices) can be structured differently, such as a p-n junction or p-i-n diode as illustrated in FIG. 1B.

FIG. 1B illustrates a cross-sectional block diagram of an alternate embodiment of the charge-separation photodetector 10 of FIG. 1A. The charge-separation photodetector 10 includes a p-type region 22 (e.g., a p-type layer), an absorber region 24 (e.g., a very lightly doped or undoped i-type region, which may be an absorber layer corresponding to the absorber region 14 of FIG. 1A), and an n-type region 26 (e.g., an n-type layer) over the substrate 12 of FIG. 1A. These may be structured as a p-n junction or a p-i-n diode. Free electrons and holes generated within the absorber layer 24, the p-type region 22, and the n-type region 26 in response to the incident photons 20 in FIG. 1A (e.g., an optical signal, sunlight, or infrared radiation) flow towards the p-type region 22 and the n-type region 26, respectively, thereby generating an electrical signal that can be detected across a p-type region electrode 28 and an n-type region electrode 30.

It should be understood that the embodiments of FIGS. 1A and 1B are illustrative in nature, and other embodiments of the present disclosure may be implemented differently. For example, some embodiments may include additional or fewer layers. Some embodiments may implement the p-type region 22, the absorber layer 24, and the n-type region 26 as horizontal regions of one or more common layers rather than separate vertical layers.

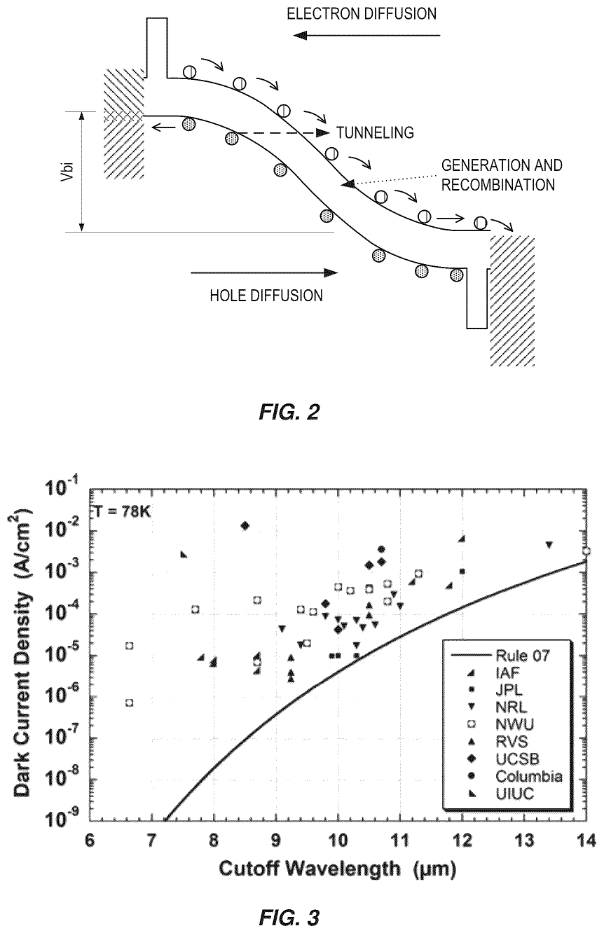

FIG. 2 illustrates a schematic diagram of a photodetector device modeled as a p-n junction or a p-i-n diode. As used herein, a photodetector device can be any solid-state device (e.g., a photoconductor, a diode, or a transistor) which operates by absorbing light energy (e.g., photons), modeled here as a p-n junction diode for illustrative purposes. Example photodetector devices include photosensors, solar cells, thermophotovoltaic devices, and so on.

Major sources of non-surface dark currents are illustrated in the p-on-n homojunction of the photodetector device at a small reverse bias. A conduction band edge, valence band edge, and Fermi level are indicated by E_{C}, E_{V}, and E_{F}, respectively. The illustrated model includes mechanisms such as Shockley-Read-Hall (SRH) recombinations, tunneling processes, and Auger processes. Dark current is an important figure of merit for an individual photodetector device. The noise associated with the dark current is often the dominant noise, as shown in FIG. 2.

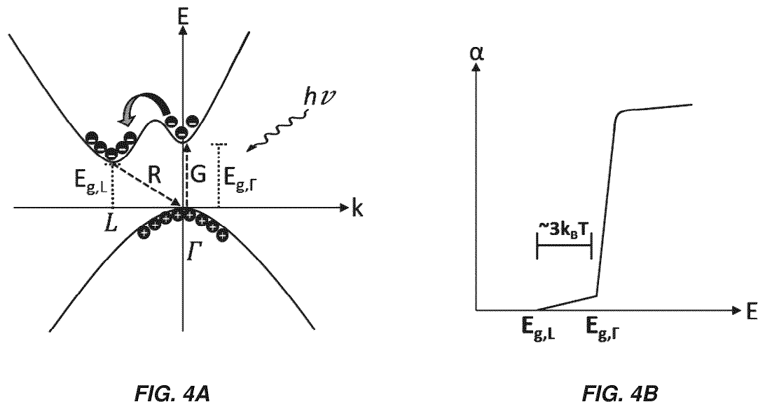

FIG. 3 is a graphical representation of published lowest dark current density data in type-II superlattice photodetectors compared with that of mercury cadmium telluride (HgCdTe, also referred to as MCT) devices (the Rule 07 curve). Based on a straightforward drift-diffusion model (such as the one that is shown in FIG. 2), the dark current density of holes diffusing from the n-type (absorber) side to the junction can be written as:

$${J}_{0} = \frac{{qn}_{i}^{2} d}{{N}_{D} τ} \qquad Equation l$$

Clearly, an ideal photodetector (e.g., a photosensor, a solar cell, or a thermophotovoltaic device) should have i) long lifetime τ; and ii) thin absorber thickness d, assuming all the signal light can be absorbed by such a thickness. In other words, the photodetector should be formed with a material that has both a very high absorption coefficient, such as in direct bandgap semiconductors (e.g., MCT or indium gallium arsenide (InGaAs)), and very long carrier lifetime, such as in indirect bandgap semiconductors (e.g., silicon (Si)).

Unfortunately, no such material has been discovered in nature. This can only be possible if one can i) tailor the band structure or spatial composition variation and ii) separate electron holes either in momentum (k)-space or in real space. Either way, recombination of photogenerated carriers, whether through SRH, radiative, or Auger recombination processes, will be strongly suppressed.

In this regard, a new set of semiconductor materials and structures are described herein, which enables the design of k-space charge-separation photodetectors with much improved photogenerated carrier lifetime and device performance. Charge-separation photodetectors use a semiconductor in the absorber region with an indirect band structure, in which the direct bandgap is only slightly above (e.g., above and near or adjacent) the indirect fundamental bandgap. In some examples, a difference between the indirect fundamental bandgap and the direct bandgap is approximately several k_{B}T (e.g., between 0.5 k_{B}T and 10 k_{B}T, between 1 k_{B}T and 8 k_{B}T, or between 2 k_{B}T and 5 k_{B}T, where k_{B} is the Boltzmann constant and T is the device operation temperature). For example, the difference between the indirect fundamental bandgap and the direct bandgap can be approximately several k_{B}T apart, such as 13 meV to 260 meV or 25 meV to 100 meV, with k_{B}T=26 meV at room temperature. A high absorption coefficient is provided by the large absorption coefficient of the direct bandgap-related absorption. In addition, a long photogenerated carrier lifetime is provided by the electrons and holes being separated in k-space, with electrons in the L or X valley in the conduction band while holes are in the valence band maximum (Γ point).

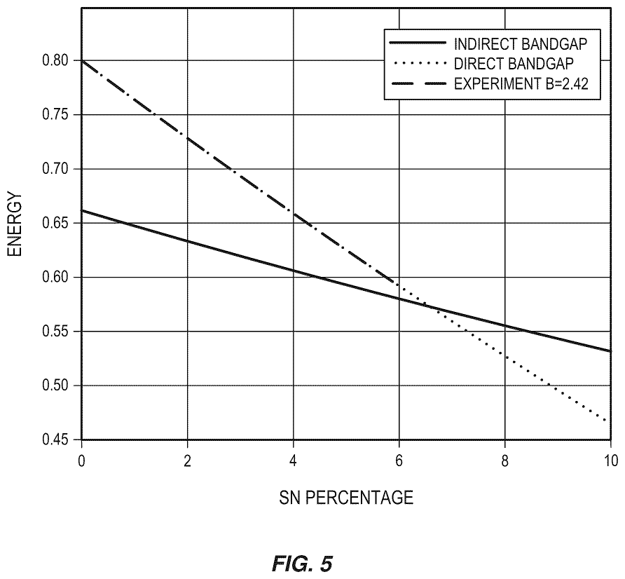

FIG. 4A illustrates the basic working principle of k-space charge-separation (k-SCS), where the energy difference between the indirect valley (L-Γ transition) and the direct valley (Γ-Γ transition) is on the order of several k_{B}T. In this regard, embodiments of the charge-separation photodetector 10 of FIG. 1A described herein are engineered to have a k-SCS band structure. The basic working principle of k-SCS is to design the band structure to have a direct energy conduction band minimum (Γ-valley) several k_{B}T (e.g., ˜2 k_{B}T-5 k_{B}T) higher than the fundamental indirect energy conduction band minimum (L- or X-valley). Here, a charge-separation energy barrier (CSEB), Δ_{Γ-L,X}, is defined as the difference between the direct-energy conduction band minimum and the fundamental indirect energy conduction band minimum, namely the energy difference between the direct valley (Γ-valley) and the lowest indirect valley (L- or X-valley). As the direct bandgap, E_{g,Γ}, has a larger absorption coefficient than its indirect counterpart, E_{g,L}, when the separation between the two is several k_{B}T, absorption is predicted to be dominated by Γ-Γ transitions, while most of the photogenerated electrons will be transferred to L- or X-valley for transport to the contact (e.g., the electrodes 16, 18 of FIG. 1A or the electrodes 28, 30 of FIG. 1B).

FIG. 4B illustrates a schematic diagram of an absorption spectrum of an exemplary charge-separation photodetector 10 of FIG. 1A, with a slow onset representing the typical feature of an indirect bandgap absorption edge and followed by a steep increase in the absorption coefficient for the transitions above the direct bandgap. In this process, electrons are photo-excited (process G) to the direct Γ-valley in the conduction band while leaving a hole in the gamma valence band. The majority of photogenerated electrons will quickly thermally relax on the order of sub-picoseconds to the lower energy indirect valley in the conduction band. Electrons in the L- or X-valley will recombine (process R) with the holes in the valance band. This increases the carrier lifetime as recombination from indirect band edges requires a change in k-space in addition to energy conservation. Then, both carriers, electrons, and holes are separately transported in the real space (with different k-values) to their corresponding contacts with miniscule recombination during the process. This design not only improves photogenerated-carrier lifetime, similar to indirect bandgap semiconductors, but also maintains a large absorption coefficient, similar to direct bandgap semiconductors. Therefore, the absorbers in the photodetectors require much thinner layers. Due to the large effective masses of the indirect valleys, the tunnelling current can also be reduced compared to direct valley semiconductors.

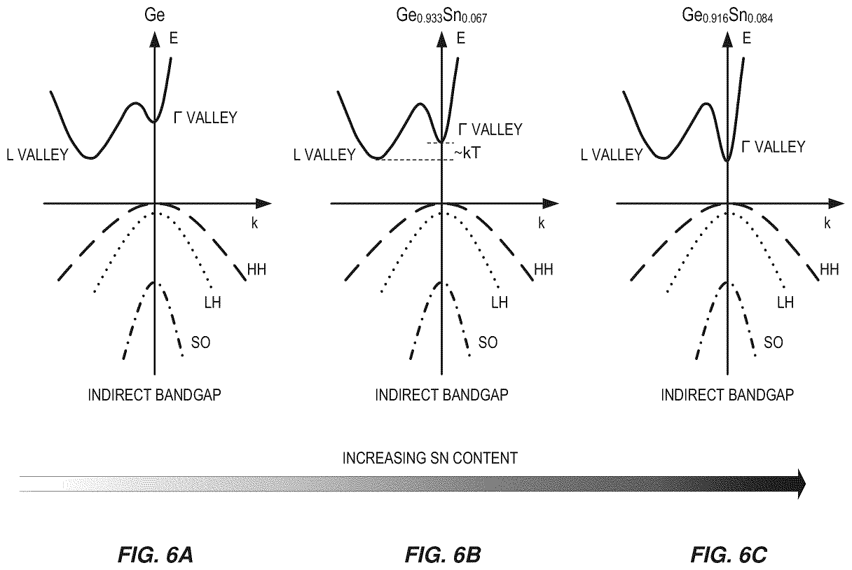

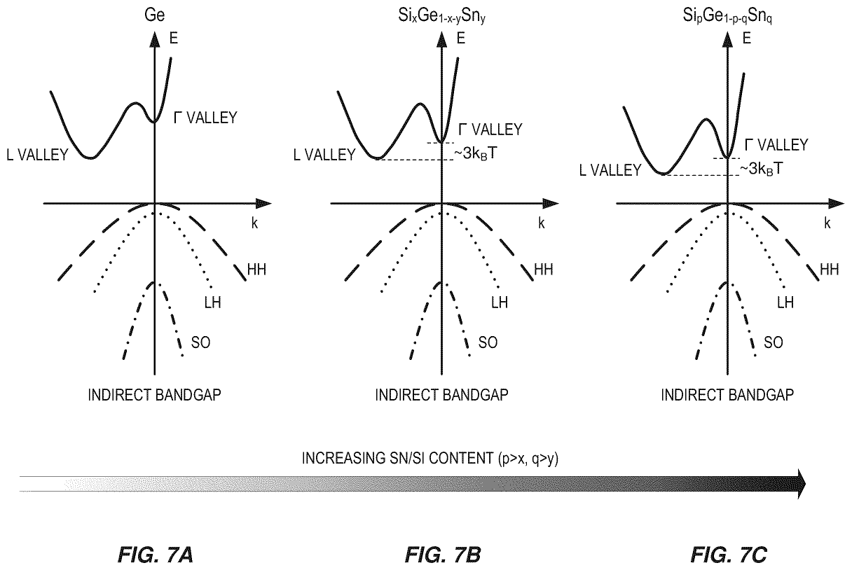

This approach can be realized using germanium-tin (GeSn) alloys. For example, when germanium (Ge), an indirect semiconductor with an L-valley fundamental bandgap, is alloyed with α-tin (α-Sn), the diamond crystal that forms is a zero-bandgap direct semiconductor. Such GeSn alloys are further described below with respect to FIGS. 5 and 6A-6C.

FIG. 5 illustrates a graphical representation of bandgap energy between the direct bandgap and the indirect fundamental bandgap as a function of Sn composition in GeSn alloy photodetectors. An SiGeSnPb material system is used in the example of FIG. 5, which can reach the mid-wavelength infrared (MWIR) region (2-5 μm) with a GeSn alloy Ge_{0.933}Sn_{0.067} and a fundamental direct bandgap of 0.57 eV (2.2 μm). FIG. 5 illustrates the changes in the direct bandgap and the indirect fundamental bandgap as a function of Sn composition (percentage) in the SiGeSnPb material system.

FIG. 6A is a graphical representation of an energy-momentum (E-k) diagram illustrating characteristics of a traditional photodetector. This photodetector uses a Ge semiconductor. FIG. 6B is a graphical representation of an E-k diagram illustrating characteristics of an embodiment of the charge-separation photodetector. This embodiment of the charge-separation photodetector uses a GeSn alloy Ge_{0.933}Sn_{0.067} semiconductor, which has a Γ valley slightly above the L-valley in the conduction band. FIG. 6C is a graphical representation of an E-k diagram illustrating characteristics of a photodetector with a direct fundamental bandgap. This photodetector uses a GeSn alloy Ge_{0.916}Sn_{0.084} semiconductor.

As Sn is alloyed with Ge, the decrease in the conduction band Γ-valley energy is greater than that of the L-valley. When enough Sn is added to GeSn, the CSEB is on the order of several k_{B}T. While this system is a promising candidate, as a binary material, the compositional range to achieve charge separation is limited as further increases in the Sn composition will continue to decrease the Γ-valley energy until it is a lower energy than L-valley, and the material is now a direct bandgap. Si, with a fundamental X-valley band edge and slightly higher energy in the L-valley band edge, will help to counteract this shift when introduced into the GeSn matrix.

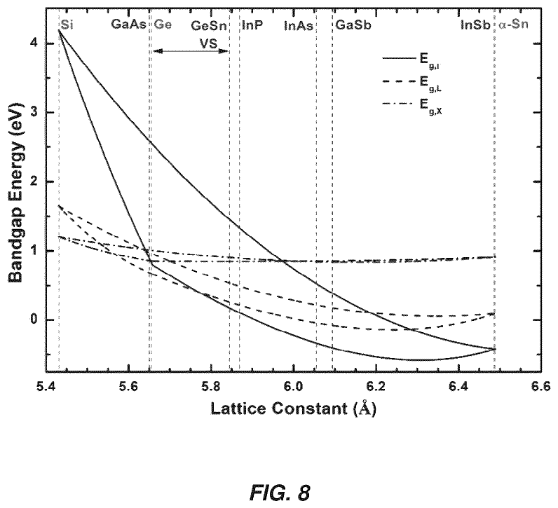

FIG. 7A is a graphical representation of an E-k diagram illustrating characteristics of a Ge-only photodetector. FIG. 7B is a graphical representation of an E-k diagram illustrating characteristics of a SiₓGe_{1-x-y}Sn_{y} embodiment of the charge-separation photodetector. FIG. 7C is a graphical representation of an E-k diagram illustrating characteristics of a longer wavelength, higher Sn/Si composition SiₚGe_{1-p-q}Sn_{q} embodiment of the charge-separation photodetector. As it becomes more Sn rich and Γ-valley energy decreased, Si will compensate to keep a CSEB with the Γ- and L-valley band edge. This allows for tunability of the wavelength that can utilize charge-separation to longer wavelengths as Sn and Si compositions are increased. In the embodiment of FIG. 7C, SiGeSn has a larger absorption coefficient than bulk Ge yet, at the same time, utilizes the long-carrier lifetime and large L-valley effective mass of Ge, lowering the tunneling current.

Embodiments of the SiGeSnPb material system (e.g., used in FIGS. 6B, 7B, and 7C) may use a substrate which includes one or more of Si, Ge, gallium arsenide (GaAs), indium phosphide (InP), indium arsenide (InAs), gallium antimonide (GaSb), indium antimonide (InSb), or sapphire (Al₂O₃). In other embodiments, other material systems can be used, such as carbon silicon germanium tin lead (CSiGeSnPb), GaAsP, AlGaAs, or GaInAlAsSb (e.g., any (GaInAl)(AsPSb) alloy) on an Si, Ge, GaAs, InP, InAs, GaSb, InSb, or Al₂O₃ substrate, depending on the alloy composition. Such materials can be used to design photo absorbers with the same properties as discussed above, namely that the direct bandgap at the Γ point is slightly above the indirect fundamental bandgap.

Band structure modeling was done using Vegard's law for bandgap energy:

$${E}_{g , i}^{SiGeSn} = {E}_{g , i}^{Si} x + {E}_{g , i}^{Sn} y + {E}_{g , i}^{Ge} ( 1 - x - y ) - {b}_{i}^{SiGe} x ( 1 - x - y ) - {b}_{i}^{SnGe} y ( 1 - x - y ) - {b}_{i}^{SiSn} x ( y ) \qquad Equation 1$$

where i is the energy valley (Γ, L, X).

Vegard's law was also used for the lattice constant:

$${a}_{0}^{SiGeSn} = {a}_{0}^{Si} x + {a}_{0}^{Sn} y + {a}_{0}^{Ge} ( 1 - x - y ) \qquad Equation 2$$

and was determined to be sufficient without introducing bowing parameters.

Modeling of the SiₓGe_{1-x-y}Sn_{y} alloy was done using bowing parameters for GeSn, SiGe, and SiSn. All values used in the modeling are shown in Table 1 (below), and assuming all films are thick and fully relaxed without introducing strain effects. Under equilibrium conditions, the solid solubility of Sn in Ge is 1%, while for that of Sn in Si is even less, requiring non-equilibrium growth conditions such as molecular-beam epitaxy (MBE) or chemical vapor deposition (CVD). The SiSn gamma-valley bowing parameter, b_{Γ}, varies from −21 to 24 eV. Currently, this variation can be, in part, attributed to differences in Si and Sn rich samples.

TABLE 1

| | Lattice | | | |
|---|---|---|---|---|
| Material | constant(Å) | E_{g,Γ}(eV) | E_{g,L}(eV) | E_{g,X}(eV) |
| Si | 5.4307 | 4.185 | 1.65 | 1.2 |
| Ge | 5.6573 | 0.7985 | 0.664 | 0.85 |
| Sn | 6.4892 | −0.413 | 0.092 | 0.91 |

| Alloy | b_{Γ}(eV) | b_{L}(eV) | b_{X}(eV) |
|---|---|---|---|
| SiGe | 0.21 | 0.335 | 0.108 |
| GeSn | 2.49 | 1.88 | 0.1 |
| SiSn | 3.915 | 2.124 | 0.772 |

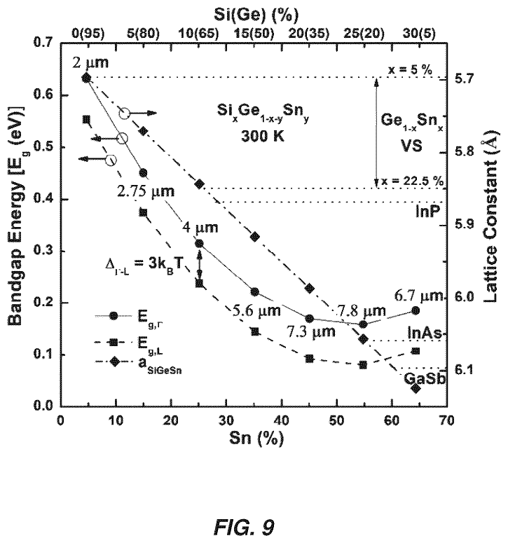

FIG. 8 illustrates a graphical representation of bandgap energy vs. lattice constant modeled for several transitions. Using Vegard's law and keeping the bowing parameters constant for the entire compositional binary range of SiGe, GeSn, and SiSn, the bandgap energy vs. lattice constant was modeled for Γ-Γ, L-Γ, and X-Γ transitions. The tertiary SiₓGe_{1-x-y}Sn_{y} transitions are restricted by these upper and lower bounds for each valley, respectively. While k-SCS can be theoretically achieved using either L- or X-indirect with Γ-direct transition, FIG. 8 shows this is more achievable in SiₓGe_{1-x-y}Sn_{y} with the L- and Γ-valley charge separation energy barrier. Commonly available, epitaxially-ready substrates are displayed along with Ge₁₋ₓSnₓ virtual substrates (GeSn-VS) with Sn concentrations varying from 0% to 22.5% to tailor lattice constant.

The CSEB can be mathematically expressed:

$${Δ}_{Γ - L} = {E}_{g , Γ} - {E}_{g , L} \qquad Equation 3$$

as both E_{g,Γ} and E_{g,L} are taken with respect to the Γ-valley valence band.

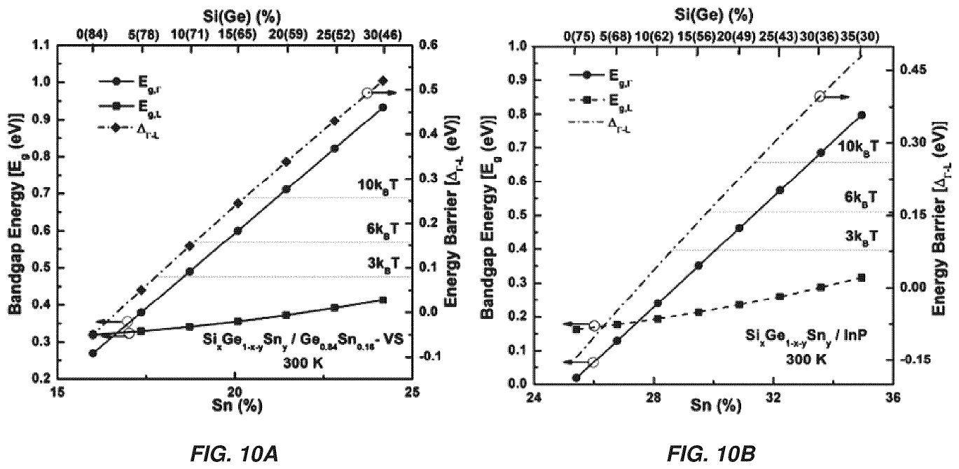

FIG. 9 illustrates a graphical representation of band structure modeling of SiₓGe_{1-x-y}Sn_{y}. With CSEB held at constant value of 3 k_{B}T at 300 K, the direct-valley absorption wavelengths range from 2 to 7.8 μm with increasing Sn and Si concentrations. This covers the entire SiₓGe_{1-x-y}Sn_{y} compositional range limit with lattice constant ranging from 5.7 to 6.1 Å. Epitaxial lattice-matched films to GeSn-VS and InP substrates can be used for MWIR applications with absorption wavelengths of 2 to 4 μm and 4.4 μm, respectively. Longer wavelengths (e.g., 7.75 and 7.3 μm) for chemical sensing can be realized using larger lattice constant substrates InAs and GaSb, respectively.

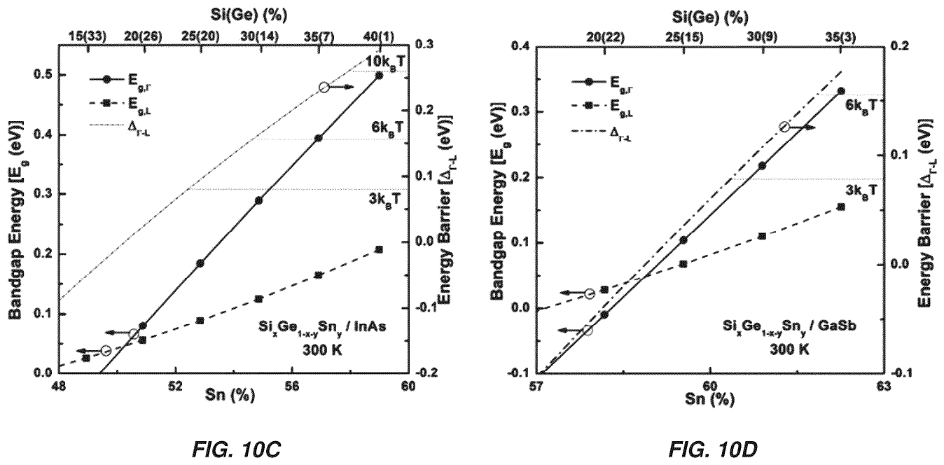

FIGS. 10A-10D illustrate graphical representations of band structure modeling of SiₓGe_{1-x-y}Sn_{y} with different substrates. In addition to keeping CSEB constant and tailoring the lattice constant, Si and Sn concentrations can be varied to keep material lattice matched to a substrate while tuning the CSEB. The CSEB required to achieve k-SCS can range from 3 to 10 k_{B}T, depending on application. Using GeSn-VS with an Sn concentration of 16%, a_{GeSn-VS}=5.7904 Å, as an example (shown in FIG. 10A), increasing CSEB to 6 k_{B}T and 10 k_{B}T decreases the absorption wavelength to 2.5 and 1.8 μm, respectively. For alloys lattice matched to InP substrate, this same increase in CSEB decreases the absorption wavelength to 3.3 and 2.5 μm (shown in FIG. 10B). For alloys lattice matched to InAs substrate, the absorption wavelength decreases to 4.4 and 2.8 μm with increase in CSEB (shown in FIG. 10C). For GaSb substrate, the alloy is approaching compositional limits and has only a dilute concentration of Ge, therefore, no CSEB of 10 k_{B}T is predicted while the absorption wavelength is 4.3 μm with 6 k_{B}T energy barrier (shown in FIG. 10D).

Those skilled in the art will recognize improvements and modifications to the preferred embodiments of the present disclosure. All such improvements and modifications are considered within the scope of the concepts disclosed herein and the claims that follow.

What is claimed is:

1. A photo-absorbing semiconductor, comprising:
a substrate;
an n-type region on the substrate;
an n-type region electrode attached to the n-type region;
an absorber region on the n-type region, wherein the absorber region has a band structure with a direct bandgap having an energy between 0.5 k_{B}T and 10 k_{B}T greater than an energy of an indirect fundamental bandgap, wherein k_{B} represents a Boltzmann constant and T represents a room temperature at which the photo-absorbing semiconductor is disposed, wherein the absorber region is formed from gallium arsenic phosphide (GaAsP), aluminum gallium arsenide (AlGaAs), gallium indium aluminum arsenic phosphorous antimonide (GaInAl)(AsPSb), silicon germanium tin lead (SiGeSnPb), or carbon silicon germanium tin lead (CSiGeSnPb);
a p-type region on the absorber region; and
a p-type region electrode attached to the p-type region.

2. The photo-absorbing semiconductor of claim 1, wherein the photo-absorbing semiconductor has a high absorption coefficient above the direct bandgap due to large absorption coefficients above direct bandgap transitions and a long carrier lifetime due to the indirect fundamental bandgap.

3. The photo-absorbing semiconductor of claim 2, wherein the high absorption coefficient of the photo-absorbing semiconductor is further due to a long lifetime of photogenerated electrons in an indirect valley.

4. The photo-absorbing semiconductor of claim 1, wherein the energy of the direct bandgap is between 1 k_{B}T and 8 k_{B}T greater than the energy of the indirect fundamental bandgap.

5. The photo-absorbing semiconductor of claim 1, wherein the energy of the direct bandgap is between 2 k_{B}T and 5 k_{B}T greater than the energy of the indirect fundamental bandgap.

6. The photo-absorbing semiconductor of claim 1, wherein the energy of the direct bandgap at the room temperature is between 13 millielectron-volts (meV) and 260 meV greater than the energy of the indirect fundamental bandgap.

7. The photo-absorbing semiconductor of claim 1, wherein the substrate comprises one or more of silicon (Si), germanium (Ge), gallium arsenide (GaAs), indium phosphide (InP), indium arsenide (InAs), gallium antimonide (GaSb), indium antimonide (InSb), or sapphire (Al₂O₃).

8. A charge-separation photodetector, comprising:
a first contact;
a second contact; and
a photo-absorbing semiconductor coupled to the first contact and the second contact, wherein the photo-absorbing semiconductor has a band structure with a direct bandgap having an energy above an energy of an indirect fundamental bandgap such that incoming photons are absorbed by direct transitions with high absorption coefficients inside the photo-absorbing semiconductor to induce a photo-generated change in an electrical property across the first contact and the second contact.

9. The charge-separation photodetector of claim 8, further comprising:
a p-type region connected to the first contact; and
an n-type region connected to the second contact;
wherein the photo-absorbing semiconductor is connected to the p-type region and the n-type region and induces a photo-generated electrical potential across the first contact and the second contact.

10. The charge-separation photodetector of claim 9, comprising at least one of a solar cell or a thermophotovoltaic device.

11. The charge-separation photodetector of claim 8, wherein a conduction band Γ-valley is above a conduction band L- or X-valley.

12. The charge-separation photodetector of claim 11, wherein the incoming photons are absorbed by the direct transitions from a valence band edge to the conduction band Γ-valley.

13. The charge-separation photodetector of claim 11, wherein photogenerated electrons and holes in the photo-absorbing semiconductor are transported to corresponding contacts with different moments inside the conduction band L- or -X valley and the conduction band Γ-valley, respectively.

14. The charge-separation photodetector of claim 13, wherein the photogenerated electrons and holes have a long lifetime due to suppressed recombination between the photogenerated electrons due to the different moments.

15. The charge-separation photodetector of claim 8, comprising a photosensor.

16. A method for producing a photodetector, the method comprising:
providing a substrate;
forming an n-type region on the substrate;
forming an n-type region electrode attached to the n-type region;
forming an absorber region on the n-type region, wherein the absorber region has a band structure with a direct bandgap having an energy between 0.5 k_{B}T and 10 k_{B}T greater than an energy of an indirect fundamental bandgap, wherein k_{B} represents a Boltzmann constant and T represents a room temperature at which a photo-absorbing semiconductor is disposed, wherein the absorber region is formed from gallium arsenic phosphide (GaAsP), aluminum gallium arsenide (AlGaAs), gallium indium aluminum arsenic phosphorous antimonide (GaInAl)(AsPSb), silicon germanium tin lead (SiGeSnPb), or carbon silicon germanium tin lead (CSiGeSnPb);
forming a p-type region on the absorber region; and
forming a p-type region electrode attached to the p-type region.

17. The method of claim 16, wherein the absorber region is formed from a silicon germanium tin lead (SiGeSnPb) material system or a carbon silicon germanium tin lead (CSiGeSnPb) material system.
